(19) United States
(12) Patent Application Publication
(10) Pub. No.: US 2025/0216785 A1
(43) Pub. Date: Jul. 3, 2025

(54) RESIST TOPCOAT COMPOSITIONS, AND METHODS OF FORMING PATTERNS USING THE COMPOSITION

(71) Applicant: SAMSUNG SDI CO., LTD., Yongin-si (KR)

(72) Inventors: Kyoungjin HA, Suwon-si (KR); Hyeon PARK, Suwon-si (KR); Ran NAMGUNG, Suwon-si (KR); Daeseok SONG, Suwon-si (KR)

(21) Appl. No.: 18/954,161

(22) Filed: Nov. 20, 2024

(30) Foreign Application Priority Data
Jan. 3, 2024 (KR) 10-2024-0001128

(51) Int. Cl. G03F 7/09; C08F 220/28; H01L 21/027

(52) U.S. Cl. CPC G03F 7/094; C08F 220/281; C08F 220/282; H01L 21/0274; C08F 2800/10

(57) ABSTRACT

A resist topcoat composition and a method of forming patterns using the resist topcoat composition, the resist topcoat composition including a copolymer including a first structural unit represented by Chemical Formula M-1, a second structural unit represented by Chemical Formula M-2, and a third structural unit represented by at least one of Chemical Formula M-3A, Chemical Formula M-3B, or Chemical Formula M-3C; and a solvent, wherein the copolymer has an OHV (OH value) of about 5 mgKOH/g to about 100 mgKOH/g.

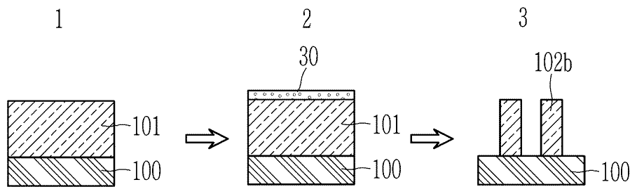

### CROSS-REFERENCE TO RELATED APPLICATION

The present application claims priority to and the benefit of Korean Patent Application No. 10-2024-0001128, filed on Jan. 3, 2024, in the Korean Intellectual Property Office, the entire content of which is incorporated herein by reference.

### BACKGROUND

### 1. Field

Embodiments of the present disclosure described herein are related to resist topcoat compositions, and methods of forming patterns using the same.

### 2. Description of the Related Art

Recently, the semiconductor industry has developed (i.e., advanced to a point where it employs) an ultrafine technique having a pattern of several to several tens nanometer size (i.e., technique capable of creating patterns that range from a few nanometers to tens of nanometers in size). Such ultrafine technique essentially needs or desires effective photolithographic processes.

Some photolithographic processes involve forming a material layer on a semiconductor substrate, coating a photoresist layer thereon, exposing and developing to form a photoresist pattern, and then etching the material layer using the photoresist pattern as a mask.

As photolithography processes develop, a degree of pattern integration is increasing, and materials and technologies for solving one or more suitable problems occurring in this process are desired or required. That is, improvement in materials and technologies used in photolithography processes may be helpful to address some of the challenges of increasing pattern integration.

For example, if (e.g., when) Extreme Ultraviolet (EUV) is irradiated to the photoresist, because there may be a region where lots of light or little light is randomly irradiated due to large energy per photon, which is a photo shot noise, or an EUV absorption difference between top and bottom of the photoresist may cause pattern distribution deterioration such as roughness (LER: line edge roughness, LWR: line width roughness) or IPU (in-point uniformity) of the patterns. In order to improve this pattern distribution deterioration, technology development may be desired or required. That is, when EUV light is exposed to the photoresist, the high energy of each photon can lead to photo shot noise, resulting in areas receiving varying amounts of light. This randomness can degrade the pattern quality due to factors like EUV absorption disparities across the photoresist's depth, leading to issues such as roughness—specifically, line edge roughness (LER) and line width roughness (LWR)—or pattern in-point uniformity (IPU). To mitigate these effects and enhance pattern uniformity, further technological advancements may be necessary or desired.

### SUMMARY

Aspects according to one or more embodiments are directed toward a resist topcoat composition capable of reducing pattern distribution by preventing or reducing pattern deterioration.

Aspects according to one or more embodiments are directed toward a method of forming patterns using the resist topcoat composition.

According to one or more embodiments, a resist topcoat composition includes a copolymer including a first structural unit represented by Chemical Formula M-1, a second structural unit represented by Chemical Formula M-2, and a third structural unit represented by at least one of Chemical Formula M-3A, Chemical Formula M-3B, or Chemical Formula M-3C; and a solvent,
wherein the copolymer has an OHV (OH value) of about 5 mgKOH/g to about 100 mgKOH/g.

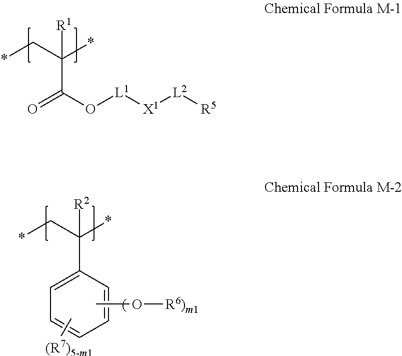

In Chemical Formula M-1 and Chemical Formula M-2,
R¹ and R² may each independently be hydrogen or a substituted or unsubstituted C1 to C10 alkyl group,
L¹ and L² may each independently be a single bond, a substituted or unsubstituted C1 to C10 alkylene group, and/or a (e.g., any suitable) combination thereof,
X¹ is a single bond, —O—, —S—, —S(═O)—, —S(═O)₂—, —C(═O)—, —C(═O)O—, —OC(═O)—, —OC(═O)O—, —NR^{a}— (wherein, R^{a} is hydrogen, deuterium, a substituted or unsubstituted C1 to C10 alkyl group), and/or a (e.g., any suitable) combination thereof,
R⁵ is hydrogen, fluorine, a hydroxyl group, a substituted or unsubstituted C1 to C20 alkyl group, and/or a (e.g., any suitable) combination thereof,
R⁶ is hydrogen, or C(═O)R^{b},
R^{b} is a substituted or unsubstituted C1 to C10 alkyl group,
at least one selected from among R⁵, L¹, and L² includes a fluorine and a hydroxyl group,
R⁷ is hydrogen, a halogen, a hydroxyl group, a substituted or unsubstituted C1 to C10 alkyl group, and/or a (e.g., any suitable) combination thereof,
m1 is one of the integers from 1 to 4, and
* is a linking point;

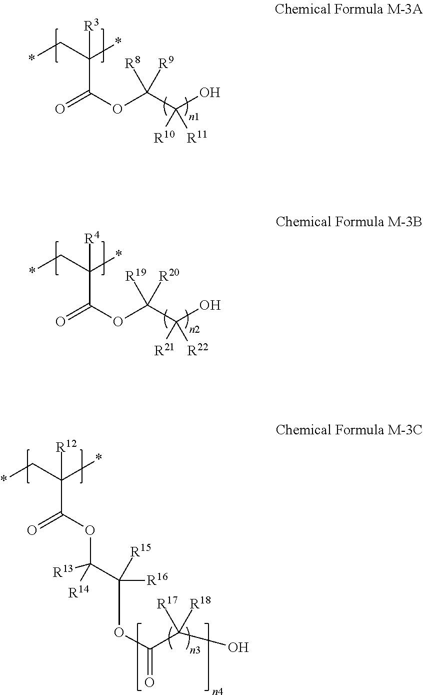

wherein, in Chemical Formula M-3A to Chemical Formula M-3C,
R³, R⁴, and R⁸ to R²² may each independently be hydrogen or a substituted or unsubstituted C1 to C10 alkyl group,
n1 and n3 may each independently be one selected from among integers of 1 to 10,
n2 is one of the integers of 2 to 5,
n4 is one of the integers of 1 to 5, and
* is a linking point.

According to one or more embodiments, a method of forming patterns may include coating and heating a photoresist composition on a substrate to form a photoresist layer, coating and heating the aforementioned resist topcoat composition on the photoresist layer to form a topcoat, and exposing and developing the topcoat and the photoresist layer to form a resist pattern.

According to one or more embodiments, the resist topcoat composition may remove excess activated acid from the top of the photoresist by introducing a structural unit having a functional group that can react with an excess activated acid, if (e.g., when) exposed with EUV, to prevent or reduce the pattern distribution deterioration such as roughness (LER, LWR) or IPU of the patterns due to EUV absorption difference between a top and a bottom of a photoresist and thus improve the pattern distribution and significantly improve IPU of pillar patterns, advantageously contributing to form fine patterns of the photoresist. That is, in accordance with certain embodiments, the resist topcoat composition is designed to eliminate surplus activated acid from the photoresist's surface. This is achieved by incorporating a structural unit equipped with a functional group that reacts with the excess activated acid. When subjected to EUV exposure, this reaction helps to prevent, minimize, or reduce the degradation of pattern uniformity, such as LER and/or LWR, and/or IPU of the patterns. This degradation is often caused by the differential absorption of EUV light between the top and bottom of the photoresist. Consequently, this improvement in pattern distribution significantly enhances the IPU or in-point uniformity of pillar patterns, thereby facilitating the formation of precise photoresist patterns.

### BRIEF DESCRIPTION OF THE DRAWING

The drawing is a schematic view for a method of forming patterns using a resist topcoat composition according to one or more embodiments.

### DETAILED DESCRIPTION

Example embodiments of the present disclosure will hereinafter be described in more detail, and may be easily performed by a person skilled in the art. However, this disclosure may be embodied in many different forms and is not construed as being limited to the example embodiments set forth herein.

In the drawings, the thickness of layers, films, panels, regions, and/or the like, are exaggerated for clarity and like reference numerals designate like elements throughout, and duplicative descriptions thereof may not be provided the specification. It will be understood that if (e.g., when) an element such as a layer, film, region, or substrate is referred to as being “on” another element, it can be directly on the other element or intervening elements may also be present. In contrast, if (e.g., when) an element is referred to as being “directly on” another element, there are no intervening elements present.

As utilized herein, expressions such as “at least one of”, “one of”, and “of (e.g., selected from among)”, when preceding a list of elements, modify the entire list of elements and do not modify the individual elements of the list. For example, “at least one of a, b or c”, “at least one selected from among a, b and c”, and/or the like, may indicate only a, only b, only c, both (e.g., simultaneously) a and b, both (e.g., simultaneously) a and c, both (e.g., simultaneously) b and c, all of a, b, and c, or variations thereof.

The term utilized herein is intended to describe only a specific embodiment and is not intended to limit the present disclosure. As utilized herein, the singular forms “a,” “an,” and “the” are intended to include the plural forms, including “at least one,” unless the content (e.g., amount) clearly indicates otherwise. “At least one” should not be construed as being limited to the singular. As utilized herein, the term “and/or” includes any and all combinations of one or more of the associated listed items. The terms “includes,” “including,” “comprises,” and/or “comprising,” when utilized in the detailed description, specify a presence of stated features, regions, integers, steps, operations, elements, and/or components, but do not preclude the presence or addition of one or more other features, regions, integers, steps, operations, elements, components, and/or groups thereof.

Spatially relative terms such as “beneath,” “below,” “lower,” “above,” and “upper” may be utilized herein to easily describe one element or feature's relationship to another element or feature. It will be understood that the spatially relative terms are intended to encompass different orientations of a device in utilize or operation in addition to the orientation illustrated in the drawings. For example, when a device in the drawings is turned over, elements described as “below” or “beneath” other elements or features would then be “above” or “over” the other elements or features. In some embodiments, the example term “below” may encompass both (e.g., simultaneously) orientations of above and below. The device may be otherwise oriented (rotated 90 degrees or at other orientations), and the spatially relative terms utilized herein may be interpreted accordingly.

As utilized herein, the term “substantially” and similar terms are utilized as terms of approximation and not as terms of degree, and are intended to account for the inherent deviations in measured or calculated values that would be recognized by those of ordinary skill in the art. Also, the term “about” and similar terms, when utilized herein in connection with a numerical value or a numerical range, are inclusive of the stated value and a value within an acceptable range of deviation for the particular value as determined by one of ordinary skill in the art, considering the measurement in question and the error associated with measurement of the particular quantity (e.g., the limitations of the measurement system). For example, “about” may refer to within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art would appreciate, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the context of the present application and unless otherwise defined, the terms “use,” “using,” and “used” may be considered synonymous with the terms “utilize,” “utilizing,” and “utilized,” respectively.

Further, the use of “may” when describing embodiments of the inventive concept refers to “one or more embodiments of the inventive concept.” Also, the term “exemplary” is intended to refer to an example or illustration.

As used herein, if (e.g., when) a definition is not otherwise provided, “substituted” refers to replacement of a hydrogen atom of a compound by a substituent selected from among a halogen atom (e.g., F, Br, Cl, or I), a hydroxyl group, a thiol group, a nitro group, a cyano group, an amino group, a substituted or unsubstituted C1 to C30 amine group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C6 to C30 allyl group, a C1 to C30 alkoxy group, a C1 to C30 sulfide group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and/or a (e.g., any suitable) combination thereof.

As used herein, if (e.g., when) a definition is not otherwise provided, “alkyl group” refers to a linear or branched aliphatic hydrocarbon group. The alkyl group may be “saturated alkyl group” without any double bond or triple bond.

The alkyl group may be a C1 to C20 alkyl group. For example, the alkyl group may be a C1 to C10 alkyl group or a C1 to C6 alkyl group. For example, a C1 to C5 alkyl group refer to that the alkyl chain includes 1 to 5 carbon atoms, and may be selected from among methyl, ethyl, propyl, iso-propyl, n-butyl, iso-butyl, sec-butyl, and tert-butyl.

The alkyl group refers to a methyl group, an ethyl group, a propyl group, an isopropyl group, a butyl group, an isobutyl group, a tert-butyl group, a pentyl group, a hexyl group, and/or the like.

In the chemical formulas described herein, t-Bu refers to a tert-butyl group.

As used herein, if (e.g., when) a definition is not otherwise provided, “cycloalkyl group” refers to a monovalent cyclic aliphatic hydrocarbon group.

The cycloalkyl group refers to a cyclopropyl group, a cyclobutyl group, a cyclopentyl group, a cyclohexyl group, and/or the like.

The cycloalkyl group may be a C3 to C10 cycloalkyl group, for example, a C3 to C8 cycloalkyl group, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but the present disclosure is not limited thereto.

As used herein, unless otherwise defined, “alkenyl group” refers to an aliphatic unsaturated alkenyl group including at least one double bond as a linear or branched aliphatic hydrocarbon group.

As used herein, unless otherwise defined, “alkynyl group” refers to an aliphatic unsaturated alkynyl group including at least one triple bond as a linear or branched aliphatic hydrocarbon group.

As used herein, “aryl group” refers to a substituent in which all atoms in the cyclic substituent have a p-orbital and these p-orbitals are conjugated and may include a monocyclic or fused ring polycyclic functional group (i.e., rings sharing adjacent pairs of carbon atoms) functional group.

As used herein, if (e.g., when) a definition is not otherwise provided, “hetero” refers to one including 1 to 10 heteroatoms selected from among N, O, S, and P.

In the present disclosure, if (e.g., when) a definition is not otherwise provided, “heterocycloalkyl group” refers to a cycloalkyl group containing at least one hetero atom selected from among N, O, S, P, and Si.

In the present disclosure, “heteroaryl group” refers to an aryl group including at least one hetero atom selected from among N, O, S, P, and Si. Two or more heteroaryl groups are linked by a sigma bond directly, or if (e.g., when) the heteroaryl group includes two or more rings, the two or more rings may be fused. When the heteroaryl group is a fused ring, each ring may include 1 to 3 hetero atoms.

Unless otherwise specified in the present specification, the weight average molecular weight is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

In addition, unless otherwise defined in the specification, “*” indicates a linking point of a structural unit or a compound moiety of a compound.

Hereinafter, a resist topcoat composition according to one or more embodiments is described.

The present disclosure relates to a photoresist topcoat composition capable of improving IPU (in-point uniformity) of C/H (contact hole) patterns, LER (line edge roughness)/LWR (line width roughness) of L/S (line and space) patterns, and IPU of pillar patterns by improving sensitivity of a photoresist during the fine pattern-forming process of photolithography using high-energy rays such as EUV (extreme ultraviolet; wavelength: about 13.5 nm) and/or the like and concurrently (e.g., simultaneously), selectively reducing an acid concentration of the upper portion of the photoresist and a method of forming photoresist patterns by using this topcoat.

The resist topcoat composition according to one or more embodiments includes a copolymer including a first structural unit represented by Chemical Formula M-1, a second structural unit represented by Chemical Formula M-2, and a third structural unit represented by at least one of Chemical Formula M-3A, Chemical Formula M-3B, or Chemical Formula M-3C; and a solvent, wherein the copolymer has an OHV (OH value) of about 5 mgKOH/g to about 100 mgKOH/g.

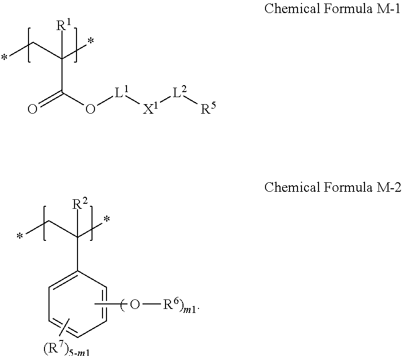

In Chemical Formula M-1 and Chemical Formula M-2,
R¹ and R² may each independently be hydrogen or a substituted or unsubstituted C1 to C10 alkyl group,
L¹ and L² may each independently be a single bond, a substituted or unsubstituted C1 to C10 alkylene group, and/or a (e.g., any suitable) combination thereof,
X¹ is a single bond, —O—, —S—, —S(═O)—, —S(═O)₂—, —C(═O)—, —C(═O)O—, —OC(═O)—, —OC(═O)O—, —NR^{a}— (wherein, R^{a} is hydrogen, deuterium, a substituted or unsubstituted C1 to C10 alkyl group), and/or a (e.g., any suitable) combination thereof,
R⁵ is hydrogen, fluorine, a hydroxyl group, a substituted or unsubstituted C1 to C20 alkyl group, and/or a (e.g., any suitable) combination thereof,
R⁶ is hydrogen, or C(═O)R^{b},
R^{b} is a substituted or unsubstituted C1 to C10 alkyl group,
at least one selected from among R⁵, L¹, or L² includes a fluorine and a hydroxyl group,
R⁷ is hydrogen, a halogen, a hydroxyl group, a substituted or unsubstituted C1 to C10 alkyl group, and/or a (e.g., any suitable) combination thereof,
m1 is one of the integers of 1 to 4, and
* is a linking point;

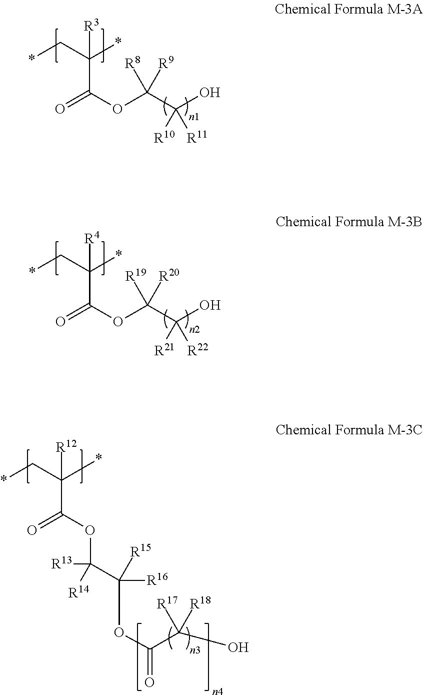

wherein, in Chemical Formula M-3A to Chemical Formula M-3C,
R³, R⁴, and R⁸ to R²² may each independently be hydrogen or a substituted or unsubstituted C1 to C10 alkyl group,
n1 and n3 may each independently be one selected from among integers of 1 to 10,
n2 is one of the integers of 2 to 5,
n4 is one of the integers of 1 to 5, and
* is a linking point.

The photoresist topcoat composition according to one or more embodiments may be coated on top of a photoresist layer to significantly improve LER/LWR of L/S patterns, IPU of C/H patterns, and IPU of pillar patterns as well as increase sensitivity of the photoresist.

The first structural unit included in the copolymer of the composition has characteristics of having almost no reactivity with the photoresist but being well dissolved in a solvent and thus may protect the photoresist, while minimizing or reducing an influence on the photoresist, and the second structural unit may increase EUV absorption to improve sensitivity. The third structural unit includes a functional group capable of reacting with acid, thereby reacting with the acid generated in excess by exposure in the upper portion of the photoresist layer, reducing a concentration of the acid and making the rounding profile of the upper layer of the photoresist rectangular to improve the IPU or LWR of the pattern.

In contrast, the photoresist topcoat composition, if (e.g., when) it remains after the development, may cause scum defects in the US patterns or not-open defects in the C/H patterns, resulting in decreasing a product yield.

However, the photoresist topcoat composition according to one or more embodiments may be removed during the development process and thus cause no defects in one or more suitable patterns. That is, the photoresist topcoat composition according to one or more embodiments of the present disclosure may be more readily removed, which can help reduce or prevent defects in the one or more suitable patterns.

The OHV (OH value) refers to an amount of hydroxyl group (—OH) expressed in mg of KOH per 100 g of sample, and analysis methods can be found in ASTM, and/or the like. For example, in the context of the present disclosure, OHV or OH value stands for hydroxyl value. The hydroxyl value is a measure of the amount of hydroxyl groups (—OH) in the sample, typically expressed in milligrams of potassium hydroxide (mgKOH) per gram (mgKOH/g).

OHV according to one or more embodiments can be measured in the following method.

A certain amount of copolymer is added to a container including a phthalic acid hydrate solution, is reacted at high temperature, is titrated with 0.5 N NaOH (or KOH) aqueous solution, and pH is observed, and an amount of NaOH (or KOH) desired or required to reach the inflection point is measured. In addition, a separate blank test is performed to measure an amount of NaOH (or KOH) desired or required to reach the pH inflection point as before. Then, based on the measured values, the OHV of the copolymer is calculated by Equation 1.

Number of mg of KOH(mgKOH/g)/equivalent of OH=56,100/equivalent of OH Equation 1

As an example, the copolymer has an OHV (OH value) of about 5 to about 90 mgKOH/g, specifically about 5 mgKOH/g to about 80 mgKOH/g, more specifically about 5 to about 70 mgKOH/g, and most specifically about 5 mgKOH to about 68 mgKOH.

In Chemical Formula M-2, if (e.g., when) m1 is 2 or more, each O—R⁶ may be the same or different from each other.

In Chemical Formula M-2, if (e.g., when) 5-m1 is 2 or more, each R⁷ may be the same or different from each other.

In Chemical Formula M-3A, if (e.g., when) n1 is 2 or more, each R¹⁰ may be the same or different from each other.

In Chemical Formula M-3A, if (e.g., when) n1 is 2 or more, each R¹¹ may be the same or different from each other.

In Chemical Formula M-3B, if (e.g., when) n2 is 2 or more, each R¹⁹ may be the same or different from each other.

In Chemical Formula M-3B, if (e.g., when) n2 is 2 or more, each R²⁰ may be the same or different from each other.

In Chemical Formula M-3B, if (e.g., when) n2 is 2 or more, each R²¹ may be the same or different from each other.

In Chemical Formula M-3B, if (e.g., when) n2 is 2 or more, each R²² may be the same or different from each other.

In Chemical Formula M-3C, if (e.g., when) n3 is 2 or more, each R¹⁷ may be the same or different from each other.

In Chemical Formula M-3C, if (e.g., when) n3 is 2 or more, each R¹⁸ may be the same or different from each other.

The terminology that at least one selected from among R⁵, L¹, and L² includes a fluorine and a hydroxyl group may refer to (e.g., at least one of R⁵, L¹, or L² contains both a fluorine and a hydroxyl group could imply) the following:
R⁵ is a C1 to C10 alkyl group substituted with at least one fluorine and at least one hydroxyl group, or
at least one selected from among L¹ and L² is a C1 to C10 alkylene group substituted with one or more fluorine groups and one or more hydroxyl groups, or
at least one selected from among L¹ and L² is a C1 to C10 alkylene group substituted with one or more fluorine groups, and at least one of the others is a C1 to C10 alkylene group substituted with one or more hydroxyl groups, or
R⁵ is fluorine, and at least one selected from among L¹ and L² is a C1 to C10 alkylene group substituted with one or more hydroxyl groups, or
R⁵ is a hydroxyl group, and at least one selected from among L¹ and L² is a C1 to C10 alkylene group substituted with one or more fluorine groups, or
R⁵ is a C1 to C10 alkyl group substituted with one or more fluorine groups and one or more hydroxyl groups, or
R⁵ is a C1 to C10 alkyl group substituted with one or more hydroxyl groups and one or more C1 to C10 fluoroalkyl groups.

As an example, the first structural unit may be represented by Chemical Formula 1.

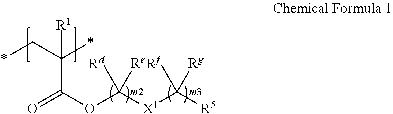

In Chemical Formula 1,
R¹ is hydrogen or a substituted or unsubstituted C1 to C10 alkyl group,
R^{d}, R^{e}, R^{f}, R^{g}, and R⁵ may each independently be hydrogen, fluorine, a hydroxyl group, a substituted or unsubstituted C1 to C20 alkyl group, and/or a (e.g., any suitable) combination thereof,
m2 and m3 may each independently be one selected from among integers of 1 to 10,
X¹ is a single bond, —O—, —S—, —S(═O)—, —S(═O)₂—, —C(═O)—, —C(═O)O—, —OC(═O)—, —OC(═O)O—, —NR^{a}— (wherein, R^{a} is hydrogen, deuterium, or a substituted or unsubstituted C1 to C10 alkyl group), and/or a (e.g., any suitable) combination thereof,
at least one selected from among R^{d}, R^{e}, R^{f}, R^{g}, and R⁵ includes fluorine and a hydroxyl group, and
* is a linking point.

In Chemical Formula 1, if (e.g., when) m2 is 2 or more, each R^{d} may be the same or different from each other.

In Chemical Formula 1, if (e.g., when) m2 is 2 or more, each R^{e} may be the same or different from each other.

In Chemical Formula 1, if (e.g., when) m3 is 2 or more, each R^{f} may be the same or different from each other.

In Chemical Formula 1, if (e.g., when) m3 is 2 or more, each R^{g} may be the same or different from each other.

This terminology that at least one selected from among R^{d}, R^{e}, R^{f}, R^{g}, and R⁵ includes a fluorine and a hydroxyl group may refer to the following:
at least one selected from among R^{d}, R^{e}, R^{f}, R^{g}, and R⁵ is each independently a fluorine group and a hydroxyl group, or
at least one selected from among R^{d}, R^{e}, R^{f}, R^{g}, and R⁵ each independently includes a C1 to C10 alkyl group substituted with one or more fluorine groups and a C1 to C10 alkyl group substituted with one or more hydroxyl groups, or
at least one selected from among R^{d}, R^{e}, R^{f}, R^{g}, and R⁵ each independently includes a C1 to C10 alkyl groups substituted with one or more hydroxyl groups and one or more fluorine groups, or
at least one selected from among R^{d}, R^{e}, R^{f}, R^{g}, and R⁵ each independently includes a C1 to C10 alkyl group substituted with one or more hydroxyl groups and one or more C1 to C10 fluoroalkyl groups, or
at least one selected from among R^{d}, R^{e}, R^{f}, R^{g}, and R⁵ is fluorine, and at least one of the others is a hydroxyl group, or
at least one selected from among R^{d}, R^{e}, R^{f}, R^{g}, and R⁵ is fluorine, and at least one of the others includes a C1 to C10 alkyl group substituted with one or more hydroxyl groups, or
at least one selected from among R^{d}, R^{e}, R^{f}, R^{g}, and R⁵ is a hydroxyl group, and at least one of the others includes a C1 to C10 alkyl group substituted with one or more fluorine groups, or
at least one selected from among R^{d}, R^{e}, R^{f}, R^{g}, and R⁵ is a C1 to C20 alkyl group substituted with one or more fluorine groups, and at least one of the others is a C1 to C20 alkyl group substituted with one or more hydroxyl groups.

For example, R¹ may be hydrogen or a methyl group,
X¹ may be a single bond, O, or NR^{a} (where R^{a} is hydrogen, deuterium, or a C1 to C10 alkyl group), and
R⁵ may be fluorine, a hydroxyl group, a C1 to C10 alkyl group substituted with at least one fluorine, or a C1 to C10 alkyl group substituted with at least one hydroxyl group.

As an example, at least one of R^{f}, R^{g}, or R⁵ in Chemical Formula 1 may include a fluorine group and a hydroxyl group.

As a specific example, at least one of R^{f} or R^{g} in Chemical Formula 1 may be fluorine or a C1 to C10 alkyl group substituted with at least one fluorine, and R⁵ may be a hydroxyl group or a C1 to C10 alkyl group substituted with at least one hydroxyl group.

As a specific example, at least one of R^{f} or R^{g} in Chemical Formula 1 may be a hydroxyl group or a C1 to C10 alkyl group substituted with at least one hydroxyl group, and R⁵ may be fluorine or a C1 to C10 alkyl group substituted with at least one fluorine.

As a specific example, R^{f} in Chemical Formula 1 may be a hydroxyl group or a C1 to C10 alkyl group substituted with at least one hydroxyl group, R^{g} may be fluorine or a C1 to C10 alkyl group substituted with at least one fluorine, R⁵ may be a hydroxyl group, fluorine, or a C1 to C10 alkyl group substituted with at least one of fluorine or hydroxyl groups.

As a specific example, at least one of R^{f} or R^{g} in Chemical Formula 1 may be fluorine or a C1 to C10 alkyl group substituted with at least one fluorine, and R⁵ may be a hydroxyl group, or a C1 to C5 alkyl group substituted with at least one of a hydroxyl group or a substituted C1 to C5 fluoroalkyl group.

For example, the first structural unit may be any one selected from among Group I.

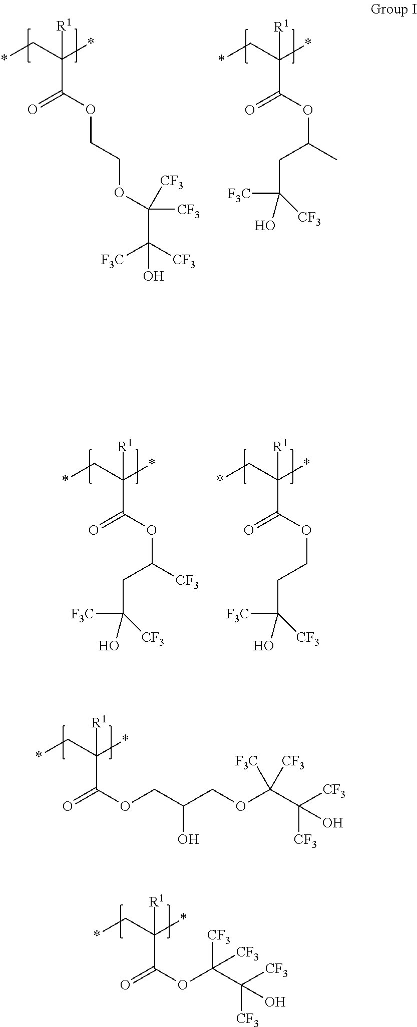

In Group I,
R¹s may each independently be hydrogen or a methyl group, and * is a linking point.

As a specific example, the second structural unit may be represented by any one selected from among Chemical Formula 2-1 to Chemical Formula 2-4.

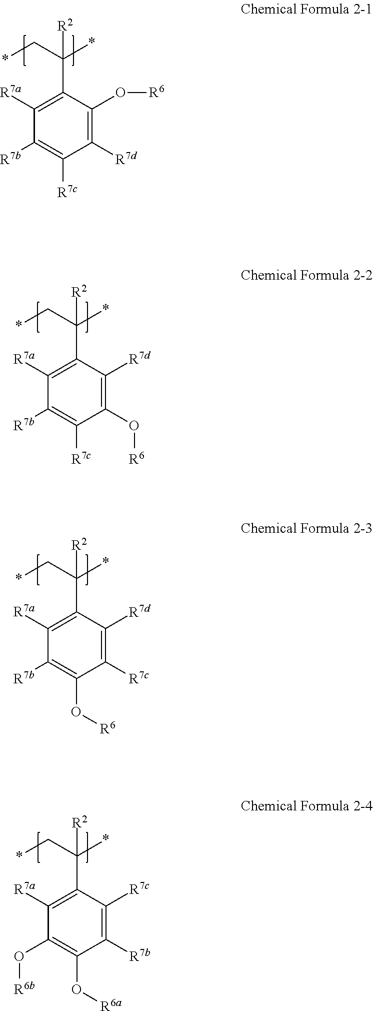

In Chemical Formula 2-1 to Chemical Formula 2-4,
R² is hydrogen or a methyl group,
R⁶, R^{6a}, and R^{6b} may each independently be hydrogen, or C(═O)R^{b},
R^{b} is a substituted or unsubstituted C1 to C5 alkyl group,
R^{7a}, R^{7b}, R^{7c}, and R^{7d} may each independently be hydrogen, halogen, a hydroxyl group, a substituted or unsubstituted C1 to C10 alkyl group, and/or a (e.g., any suitable) combination thereof, and
* is a linking point.

As an example, at least one of R⁷ may be a halogen.

As an example, at least one of R⁷ may be an iodine group.

If (e.g., when) the second structural unit includes an iodine group, sensitivity can be further improved.

For example, the second structural unit may be any one selected from among Group II.

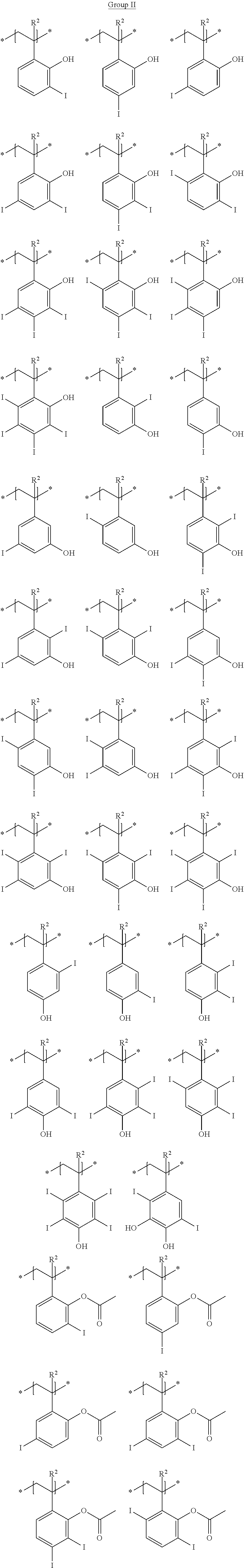

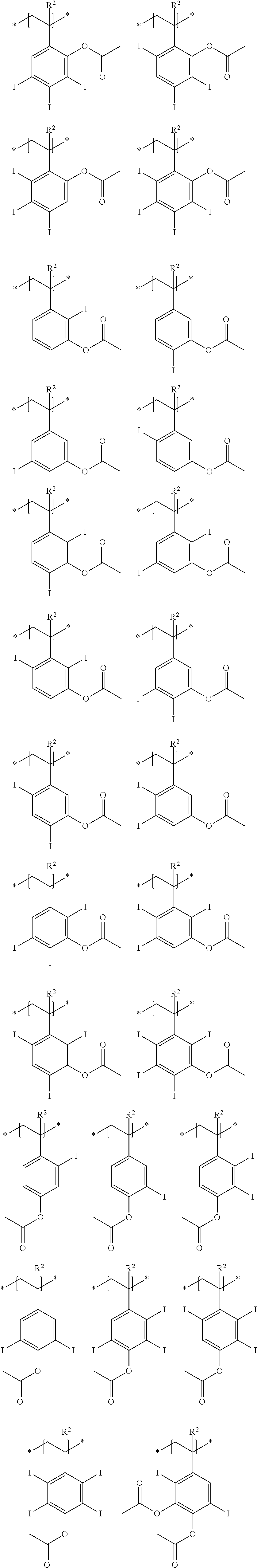

In Group II,
R² may each independently be hydrogen or a methyl group, and * is a linking point.

For example, L³ to L⁷ may each independently be a single bond, a substituted or unsubstituted C1 to C5 alkylene group, or a substituted or unsubstituted phenylene group,
R⁸ to R¹⁴ may each independently be hydrogen, or a substituted or unsubstituted C1 to C10 alkyl group, and
n1 may be an integer of 1 or 2.

As an example, n1 in Chemical Formula M-3A may be one of the integers of 1 to 5.

As an example, n2 in Chemical Formula M-3B may be one of the integers of 2 to 4.

As an example, n3 in Chemical Formula M-3C may be one of the integers of 1 to 5.

For example, the third structural unit may be any one selected from among Group III.

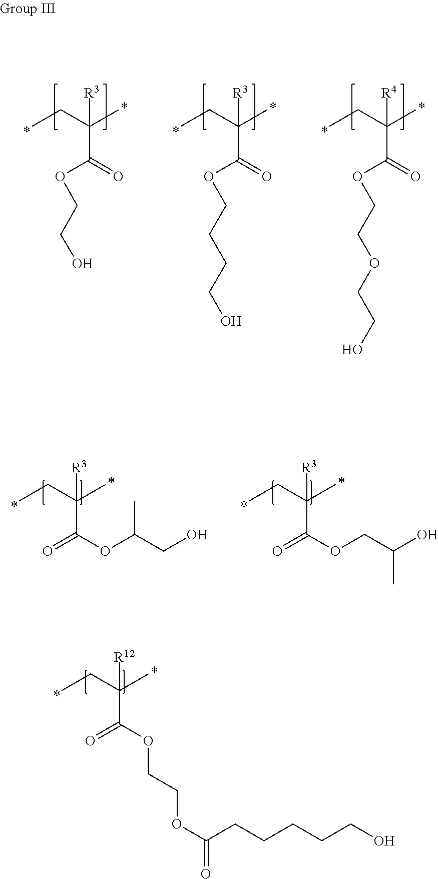

In Group III,
R³, R⁴ and R¹² may each independently be hydrogen or a methyl group, and * is a linking point.

The copolymer may include about 30 mol % to about 95 mol % of the first structural unit, about 1 mol % to about 20 mol % of the second structural unit, and about 5 mol % to about 50 mol % of the third structural unit.

For example, the copolymer may include about 55 mol % to about 90 mol % of the first structural unit, about 5 mol % to about 15 mol % of the second structural unit, and about 5 mol % to about 30 mol % of the third structural unit, and in one or more embodiments, the copolymer may include about 60 mol % to about 85 mol % of the first structural unit, about 5 mol % to about 15 mol % of the second structural unit, and about 5 mol % to about 25 mol % of the third structural unit.

If (e.g., when) the mole ratio of each structural unit included in the copolymer is within the above ranges, the solubility in organic solvents is improved and the pattern can be uniformly (e.g., substantially uniformly) coated.

The copolymer may have a weight average molecular weight (Mw) of about 1,000 g/mol to about 15,000 g/mol. For example, it may have a weight average molecular weight of about 2,000 g/mol to about 15,000 g/mol, for example about 3,000 g/mol to about 15,000 g/mol, for example about 4,000 g/mol to about 10,000 g/mol, but the present disclosure is not limited thereto. When the weight average molecular weight of the copolymer is within the above ranges, a carbon content (e.g., amount) and solubility in a solvent of the resist topcoat composition including the copolymer may be improved or optimized.

The copolymer may be included in an amount of about 0.1 wt % to about 10 wt % based on a total weight of 100 wt % of the resist topcoat composition. Within the above ranges, the resist topcoat may be more easily removed.

In one or more embodiments, the copolymer may be selected from among those listed in Group IV.

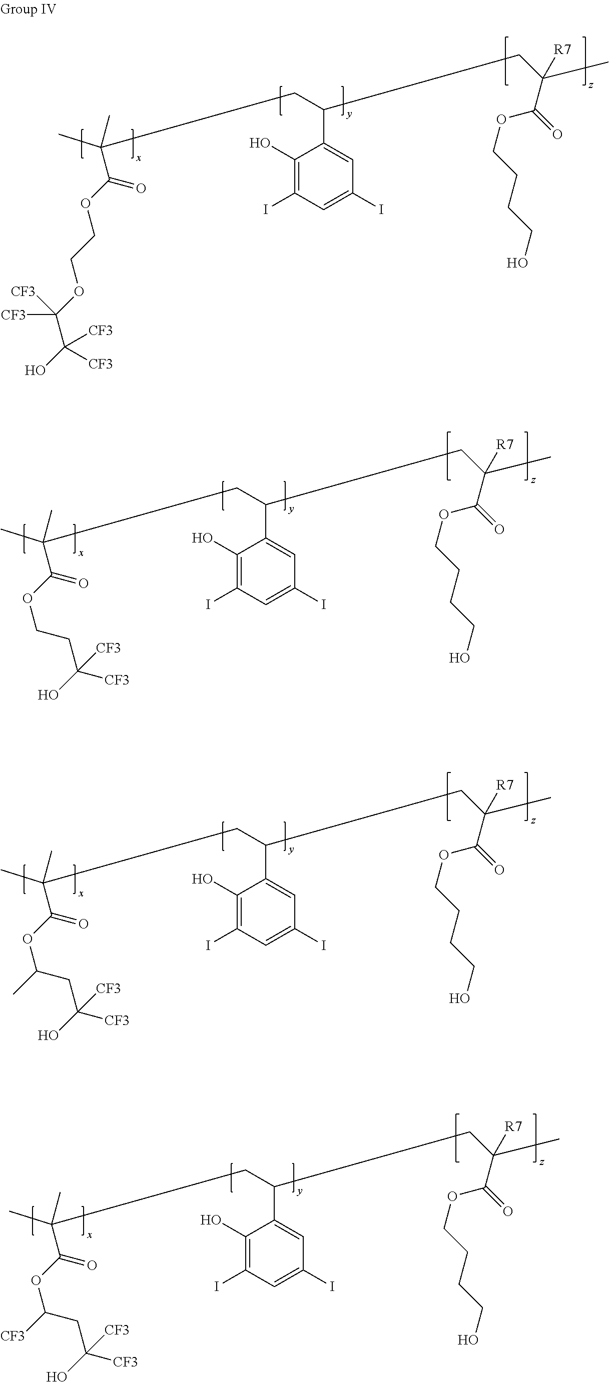

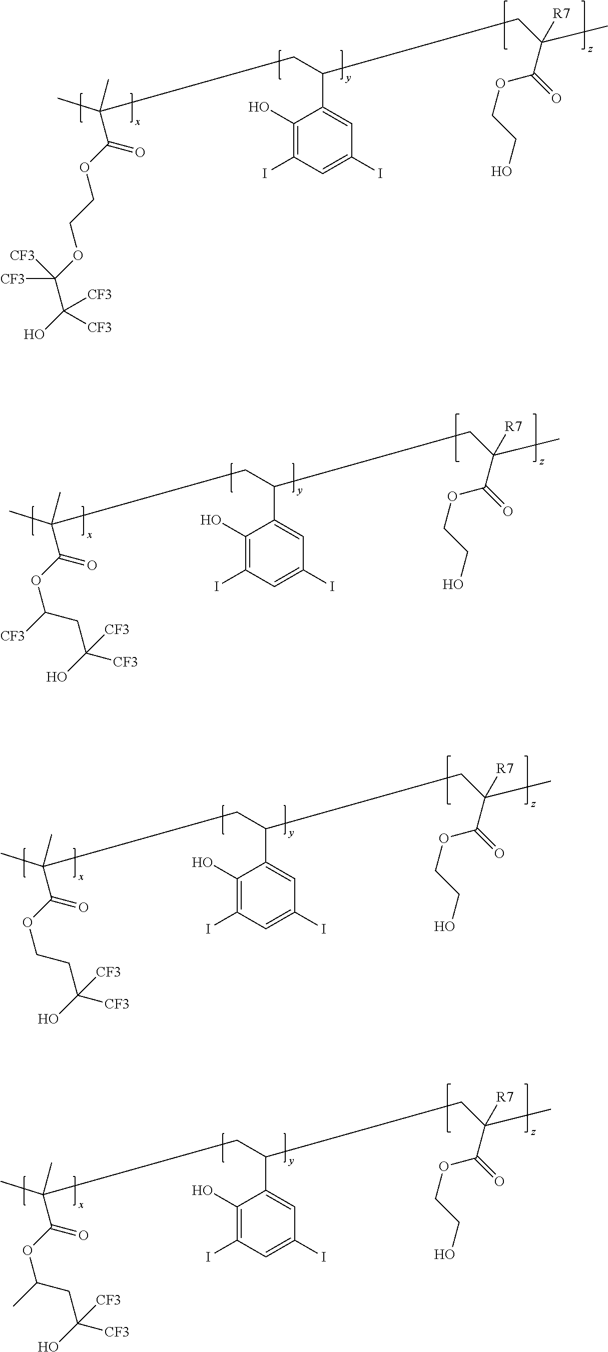

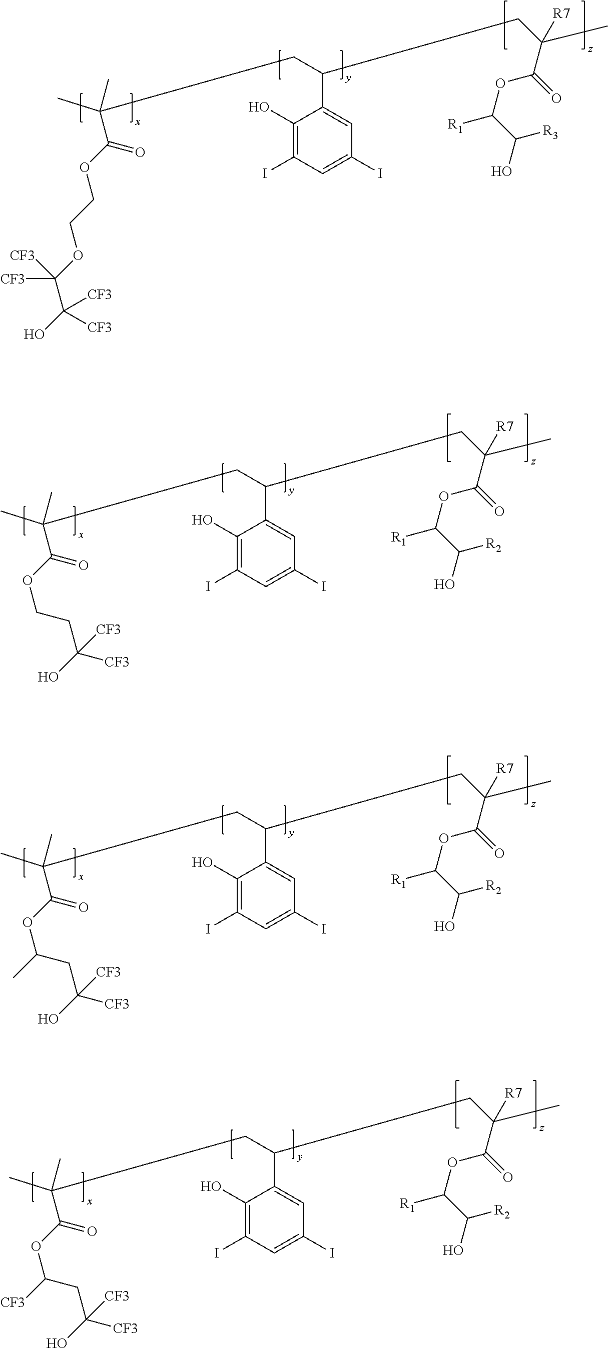

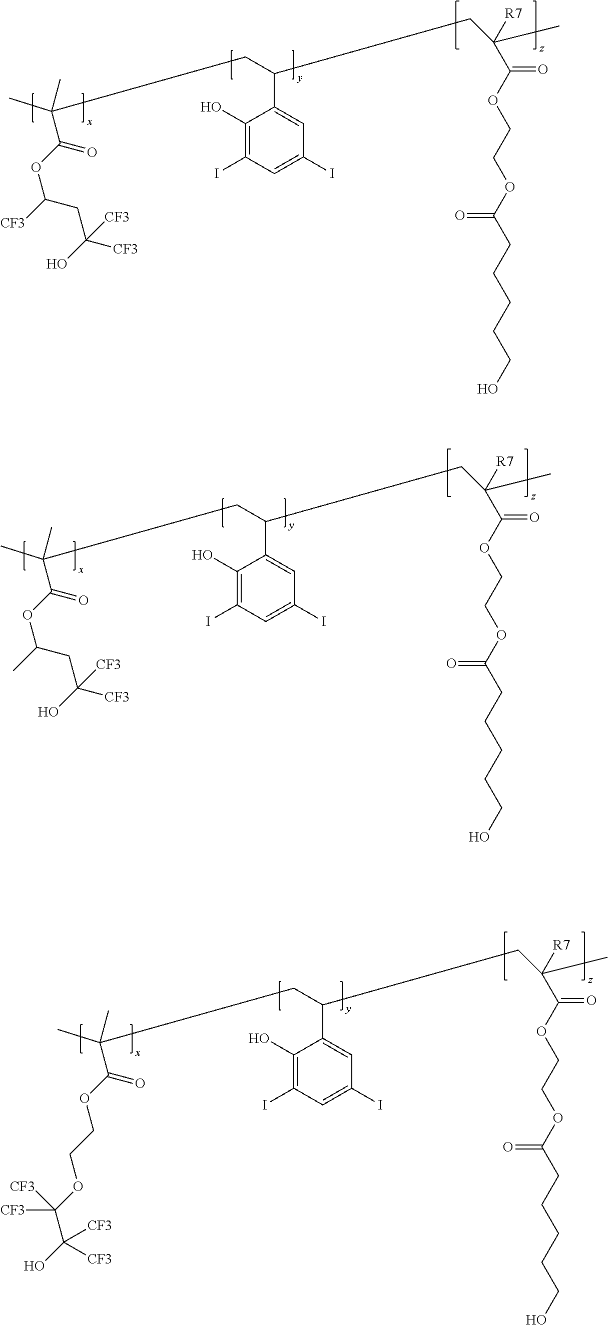

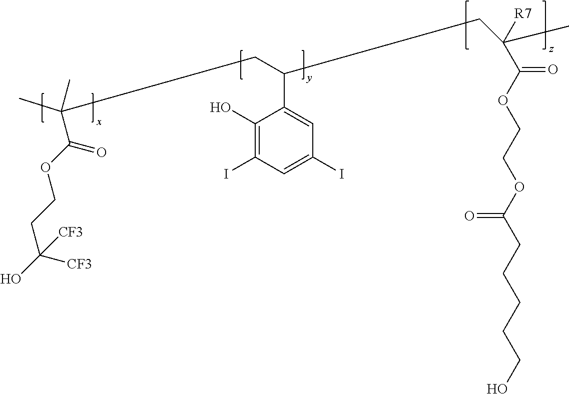

In Group IV,
R¹, R², and R⁷ may each independently be hydrogen or a methyl group,
x is about 30 mol % to about 95 mol %, y is about 2 mol % to about 20 mol %, and z is about 5 mol % to about 50 mol %.

For example, x:y:z may be about 73:10:17 or about 76:8:16 or about 77:9:14.

The solvent may be an ether-based solvent represented by Chemical Formula 4.

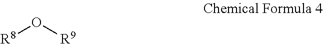

In Chemical Formula 4,
R⁸ and R⁹ may each independently be a substituted or unsubstituted C1 to C20 alkyl group or a substituted or unsubstituted C3 to C20 cycloalkyl group.

For example, the ether-based solvent may be selected from among diisopropyl ether, dipropyl ether, diisoamyl ether, diamyl ether, dibutyl ether, diisobutyl ether, di-sec-butyl ether, dihexyl ether, bis(2-ethylhexyl) ether, didecyl ether, diundecyl ether, didodecyl ether, ditetradecyl ether, hexadecyl ether, butyl methyl ether, butyl ethyl ether, butyl propyl ether, tert-butyl methyl ether, tert-butyl ethyl ether, tert-butylpropyl ether, di-tert-butyl ether, cyclopentylmethyl ether, cyclohexylmethyl ether, cyclopentylethyl ether, cyclohexylethyl ether, cyclopentylpropyl ether, cyclopentyl-2-propyl ether, cyclohexylpropyl ether, cyclohexyl-2-propyl ether, cyclopentylbutyl ether, cyclopentyl-tert-butyl ether, cyclohexylbutyl ether, cyclohexyl-tert-butyl ether, and/or a (e.g., any suitable)combination thereof.

The ether-based solvent may have sufficient solubility or dispersibility for the aforementioned composition.

In one or more embodiments, the resist topcoat composition may further include at least one other polymer selected from among an epoxy-based resin, a novolac resin, a glycoluril-based resin, and a melamine-based resin, but the present disclosure is not limited thereto.

The resist topcoat composition may further include an additive including a surfactant, a thermal acid generator, a plasticizer, and/or a (e.g., any suitable) combination thereof.

The surfactant may be, for example, an alkylbenzene sulfonic acid salt, an alkylpyridinium salt, polyethylene glycol, a quaternary ammonium salt, and/or the like, but the present disclosure is not limited thereto.

The thermal acid generator may be, for example, an acid compound such as p-toluene sulfonic acid, trifluoromethanesulfonic acid, pyridinium p-toluene sulfonic acid, salicylic acid, sulfosalicylic acid, citric acid, benzoic acid, hydroxybenzoic acid, naphthalene carboxylic acid and/or benzoin tosylate, 2-nitrobenzyl tosylate, and other organic sulfonic acid alkyl esters, but the present disclosure is not limited thereto.

The amount of these additives used can be easily adjusted according to desired or suitable physical properties and may not be provided.

In one or more embodiments, a method of forming patterns using the aforementioned photoresist topcoat composition may be provided. For example, the manufactured pattern may be a photoresist pattern.

A method of forming patterns according to one or more embodiments includes coating and heating a photoresist composition on a substrate to form a photoresist layer, coating and heating the aforementioned photoresist topcoat composition on the photoresist layer to form a topcoat, and exposing and developing the topcoat and the photoresist layer to form a resist pattern.

Hereinafter, a method of forming patterns using the aforementioned photoresist topcoat composition will be described in more detail with reference to the drawing. The drawing is a schematic view for a method of forming patterns using a photoresist topcoat composition according to the present disclosure.

Referring to the drawing, first, an object to be etched is prepared. An example of the object to be etched may be a thin film formed on a semiconductor substrate 100. Hereinafter, only the case where the aspect to be etched is a thin film will be described. The surface of the thin film is cleaned to remove contaminants remaining on the thin film. The thin film may be, for example, a silicon nitride film, a polysilicon film, or a silicon oxide film.

A photoresist composition is coated on the thin film and heated to form a photoresist layer 101 (Step (e.g., act or task) 1). Subsequently, the photoresist topcoat composition is coated on the photoresist layer and heated to form a photoresist topcoat 30 (Step (e.g., act or task) 2).

The heating may be performed at a temperature of about 80° C. to about 500° C.

Then, the photoresist topcoat and the photoresist layer are exposed to high-energy radiation.

For example, the high-energy radiation that can be used in the exposure process may include light having a high-energy wavelength, such as EUV (Extreme Ultraviolet; wavelength: about 13.5 nm) and/or E-Beam (electron beam).

A post-exposure heat treatment (PEB) is then performed. The post-exposure heat treatment may be performed at a temperature of about 80° C. to about 200° C. By performing the post-exposure heat treatment, the exposed region of the photoresist layer, that is, the region not covered by the patterned mask is changed to a property that is soluble in a developer, so that the exposed region has a different solubility from that of the unexposed region of the photoresist layer.

A photoresist pattern 102b may be formed by dissolving and removing the photoresist layer corresponding to the exposed region and the photoresist topcoat using a developer (Step (e.g., act or task) 3).

For example, the developer may be an alkaline developer or a developer containing an organic solvent (hereinafter referred to as an organic-based developer).

As the alkaline developer, a quaternary ammonium salt such as tetramethylammonium hydroxide is usually used, but aqueous alkaline solutions such as inorganic alkalis, primary to tertiary amines, alcohol amines, and/or cyclic amines may also be used.

Moreover, the alkaline developer may contain alcohol and/or surfactant in an appropriate or suitable amount. An alkaline concentration of the alkaline developer may be, for example, about 0.1 mass % to about 20 mass %, and a pH of the alkaline developer may be, for example, about 10 to about 15.

The organic-based developer may be a developer containing at least one organic solvent selected from among ketone solvents, ester solvents, alcohol solvents, amide solvents, ether solvents, and hydrocarbon solvents.

Examples of the ketone solvent may include 1-octanone, 2-octanone, 1-nonanone, 2-nonanone, acetone, 2-heptanone(methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonyl acetone, ionone, diacetonyl alcohol, acetyl carbinol, acetophenone, methyl naphthyl ketone, isophorone, propylene carbonate, and/or the like.

Examples of the ester solvent may include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, ethylene glycol monobutyl ether acetate, ethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isoamyl acetate, isobutyl isobutyrate, butyl propionate, and/or the like.

Suitable solvents that may be used include alcohol solvents, amide solvents, ether solvents, and hydrocarbon solvents.

A plurality of said solvents may be mixed, or may be mixed with solvents or water other than the above-described solvents. A moisture content (e.g., amount) as a whole of the developer may be less than about 50 wt %, less than about 20 wt %, less than about 10 wt %, and particularly the developer may be substantially free of moisture.

A content (e.g., amount) of the organic solvent may be about 50 wt % to about 100 wt %, about 80 wt % to about 100 wt %, about 90 wt % to about 100 wt %, and about 95 wt % to about 100 wt % based on a total amount of 100 wt % of the organic developer.

The organic developer may include an appropriate or suitable amount of a suitable surfactant as desired or required. That is, the organic developer may include a suitable amount of a suitable surfactant.

A content (e.g., amount) of the surfactant may be usually about 0.001 wt % to about 5 wt %, about 0.005 wt % to about 2 wt %, and about 0.01 wt % to about 0.5 wt % based on a total amount of 100 wt % of the developer.

The organic developer may include inhibitor.

Subsequently, the exposed thin film is etched by applying the photoresist pattern as an etching mask. As a result, the thin film is formed into a thin film pattern.

The thin film may be etched, for example, by dry etching using an etching gas, and the etching gas may be, for example, CHF₃, CF₄, Cl₂, BCl₃, and/or a (e.g., any suitable) mixture thereof.

In the exposure process described above, the thin film pattern formed using the photoresist pattern that is formed by the exposure process performed using the EUV light source may have a width corresponding to the photoresist pattern. For example, the photoresist pattern may have a width of about 5 nm to about 100 nm. For example, the thin film pattern formed by the exposure process performed using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, or may be formed in a width of less than or equal to about 20 nm, like the photoresist pattern (e.g., the pattern may be formed with a maximum width of about 20 nm, akin to the photoresist pattern).

Hereinafter, the present disclosure will be described in more detail through examples relating to the synthesis of the aforementioned polymer and the preparation of a photoresist topcoat composition including the same. However, the present disclosure is not technically limited by the following examples.

### Synthesis Examples

### Synthesis Example 1

In a 250 mL 2-neck round bottom flask, 13.39 g of the compound represented by Chemical Formula 1a (Cam Optics), 1.86 g of the compound represented by Chemical Formula 1 b (DIHS, Acelachem Bio), and hydroxyl butyl acrylate (2.16 g of 4-HBA (Daejeong Chemical Co., Ltd.) and 71.4 g of diisoamyl ether (DIAE) were added and heated to an internal temperature of 115° C. When the internal temperature reaches 115° C., 13.82 g of 25 wt % V-601/DIAE solution (3.45 g of V-601) was slowly added, and after 6 hours, the reaction solution was cooled to room temperature and the reaction mixture was concentrated to have a 50% solid content (e.g., amount). After adding 120 g of heptane to the concentrated solution, the resulting polymer was filtered out. The filtered polymer was completely dissolved in 12 g of DIAE, then precipitated by adding 270 g of heptane twice, and then completely dried to finally prepare Copolymer R1 (Mw=5,000).

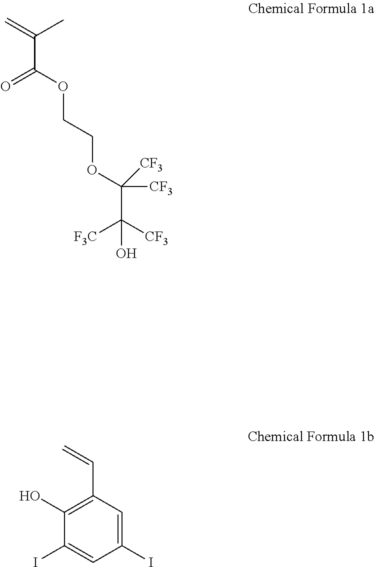 [SMILES: C=C(C)C(=O)OCCOC(C(F)(F)F)(C(F)(F)F)C(O)(C(F)(F)F)C(F)(F)F ; C=Cc1cc(I)cc(I)c1O]

### Synthesis Example 2

Copolymer R2 (Mw=5,300) was prepared in substantially the same manner as Synthesis Example 1, except that 1.74 g of hydroxyl ethyl acrylate (HEA; Daejeong Chemical Co., Ltd.) was used instead of 4-HBA.

### Synthesis Example 3

Copolymer R3 (Mw=5,500) was prepared in substantially the same manner as Synthesis Example 1, except that 1.95 g of hydroxyl propyl acrylate (HPA; Daejeong Chemical Co., Ltd.) was used instead of 4-HBA.

### Synthesis Example 4

Copolymer R4 (Mw=5,900) was prepared in substantially the same manner as Synthesis Example 1, except that 5.16 g of caprolactone acrylate (tone M-100; Dow Chemical) was used instead of 4-HBA.

### Synthesis Example 5

Copolymer R5 (Mw=5,500) was prepared in substantially the same manner as in Synthesis Example 1, except that 8.83 g of the compound represented by Chemical Formula 1c (HALOCARBON) was used instead of the compound represented by Chemical Formula 1a.

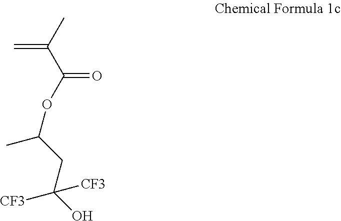 [SMILES: C=C(C)C(=O)OC(C)CC(O)(C(F)(F)F)C(F)(F)F]

### Synthesis Example 6

Copolymer R6 (Mw=5,500) was prepared in substantially the same manner as in Synthesis Example 1, except that 8.41 g of a compound represented by Chemical Formula 1d (HALOCARBON) was used instead of the compound represented by Chemical Formula 1a.

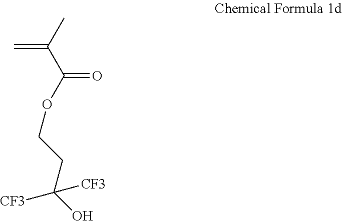 [SMILES: C=C(C)C(=O)OCCC(O)(C(F)(F)F)C(F)(F)F]

### Synthesis Example 7

Copolymer R7 (Mw=5,300) was prepared in substantially the same manner as in Synthesis Example 1, except that 9.25 g of the compound represented by Chemical Formula 1e (HALOCARBON) was used instead of the compound represented by Chemical Formula 1a.

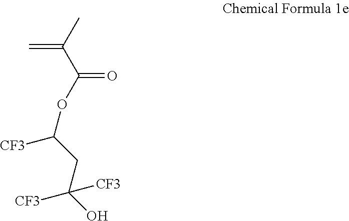 [SMILES: C=C(C)C(=O)OC(CC(O)(C(F)(F)F)C(F)(F)F)C(F)(F)F]

### Comparative Synthesis Example 1

Copolymer R8 (Mw=7,500) was prepared in substantially the same manner as in Synthesis Example 1, except that 8.92 g of the compound represented by Chemical Formula 1a and 3.61 g of 4-HBA were used.

### Comparative Synthesis Example 2

Copolymer R9 (Mw=3,100) was prepared in substantially the same manner as in Synthesis Example 1, except that 5.58 g of the compound represented by Chemical Formula 1 b and 3.45 g of 4-HBA were used.

### Comparative Synthesis Example 3

Copolymer R10 (Mw=2,700) was prepared in substantially the same manner as in Synthesis Example 1, except that 11.15 g of the compound represented by Chemical Formula 1a and 9.3 g of the compound represented by Chemical Formula 1 b were used, and 4-HBA was not used.

### Comparative Synthesis Example 4

Copolymer R11 (Mw=4,200) was prepared in substantially the same manner as in Synthesis Example 1, except that 5.58 g of the compound represented by Chemical Formula 1 b and 5.05 g of 4-HBA were used, and the compound represented by Chemical Formula 1a was not used.

### Comparative Synthesis Example 5

Copolymer R12 (Mw=8,100) was prepared in substantially the same manner as in Synthesis Example 1, except that 13.39 g of the compound represented by Chemical Formula 1a and 2.88 g of Chemical Formula 4-HBA were used, and the compound represented by Chemical Formula 1 b was not used.

### Evaluation 1: Solubility Evaluation

1 g of each copolymer prepared from Synthesis Examples 1 to 7 and Comparative Synthesis Examples 1 to 5 was taken, added to 50 g of DIAE (2 wt %), and stirred for 24 hours. The presence or absence of precipitation was observed with the naked eye, and the results are shown in Table 1.

### Evaluation Criteria

Solubility ∘: No foreign substances, transparent liquid state
Solubility Δ: No precipitate, somewhat opaque
Solubility X: precipitates are present or it is completely cloudy.

### Evaluation 2: Developability Evaluation

Each of the photoresist topcoat compositions according to Examples and Comparative Examples was spin-coated on a silicon substrate and heat-treated at 110° C. on a hot plate for 1 minute, to form an about 5 nm-thick photoresist topcoat. The substrate with a topcoat formed thereon was developed with 2.38% tetramethylammonium hydroxide aqueous solution and heat-treated again at 110° C. on the hot plate for 1 minute and then, measured with respect to a thickness change of the topcoat layer, and the results are shown in Table 1.

$${}^{*} Residual film after development ( \% ) = [ Topcoat thickness before development ( nm ) - Topcoat thickness after development ( nm ) ] \times 100 / Topcoat thickness before development ( nm )$$

### Evaluation Criteria

∘: it is 98% or more in the above Calculation Equation.
Δ: it is less than 98% and 90% or more in the above Calculation Equation
X: it is less than 90% in the above Calculation Equation

### Evaluation 3: Patterning Evaluation

After forming a resist underlayer (thickness: 50 Å) and a photoresist thin film for E-Beam (thickness: 700 Å) on an 8-inch silicon substrate, each of the photoresist topcoat compositions according to the examples and the comparative examples was spin-coated and then, heat-treated at 110° C. for 1 minute on a hot plate to form an about 5 nm-thick photoresist topcoat.

On the wafer on which the photoresist topcoat was formed, line & space patterns were formed in a focus-energy matrix (FEM) format using E-Beam equipment (JEOL JBX-9300FS). Subsequently, optimum sensitivity capable of forming a critical dimension (CD) of 50 nm was checked in an interpolation method, and the results are shown in Table 1, and
after checking the optimum sensitivity, a line width roughness (LWR) distribution at the corresponding energy shot was measured by using CD-SEM equipment made by Hitachi Ltd., and the same patterns at 500 points were measured within the shot in order to reliability of the distribution, and final average values thereof are shown in Table 1.

TABLE 1

| | | OHV | | | Sensitivity | |
|---|---|---|---|---|---|---|
| | Copolymer | (mgKOH/g) | Solubility | Developability | (mJ/cm²) | LWR |
| Example 1 | R1 | 48.3 | ◯ | ◯ | 33.2 | 2.0 |
| Example 2 | R2 | 49.5 | ◯ | ◯ | 34.1 | 2.3 |
| Example 3 | R3 | 48.9 | ◯ | ◯ | 34.6 | 2.2 |
| Example 4 | R4 | 41.2 | ◯ | ◯ | 35.2 | 2.5 |
| Example 5 | R5 | 65.5 | ◯ | ◯ | 33.2 | 2.7 |
| Example 6 | R6 | 67.7 | ◯ | ◯ | 33.4 | 2.4 |
| Example 7 | R7 | 63.4 | ◯ | ◯ | 33.3 | 2.5 |
| Comparative | R8 | 3.9 | ◯ | X | 37.8 | 3.4 |
| Example 1 | | | | | | |
| Comparative | R9 | 0 | ◯ | X | 36.8 | 3.1 |
| Example 2 | | | | | | |
| Comparative | R10 | 184.8 | X | ◯ | 32.7 | 3.8 |
| Example 3 | | | | | | |
| Comparative | R11 | 69 | Δ | ◯ | 34.3 | 2.8 |
| Example 4 | | | | | | |
| Comparative | R12 | 132.1 | X | ◯ | 33.8 | 3.6 |
| Example 5 | | | | | | |

Referring to Table 1, if (e.g., when) the resist topcoat compositions according to one or more embodiments were applied, not only is the sensitivity excellent or suitable, but the LWR improvement effect is also excellent or suitable.

Relevant devices or components using the resist topcoat composition according to embodiments of the present disclosure described herein may be implemented utilizing any suitable hardware, firmware (e.g. an application-specific integrated circuit), software, or a combination of software, firmware, and hardware. For example, the one or more suitable components of the device may be formed on one integrated circuit (IC) chip or on separate IC chips. Further, the one or more suitable components of the device may be implemented on a flexible printed circuit film, a tape carrier package (TCP), a printed circuit board (PCB), or formed on one substrate. Further, the one or more suitable components of the device may be a process or thread, running on one or more processors, in one or more computing devices, executing computer program instructions and interacting with other system components for performing the one or more suitable functionalities described herein. The computer program instructions are stored in a memory which may be implemented in a computing device utilizing a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the scope of the present disclosure.

Hereinbefore, the certain embodiments of the present disclosure have been described and illustrated, however, it is apparent to a person with ordinary skill in the art that the present disclosure is not limited to one or more embodiments as described, and may be variously modified and transformed without departing from the spirit and scope of the present disclosure. Accordingly, the modified or transformed embodiments as such may not be understood separately from the technical ideas and aspects of present disclosure, and the modified embodiments are within the scope of the claims and equivalents thereof of the present disclosure.

### REFERENCE NUMERALS

1: forming a photoresist layer
2: forming a photoresist topcoat
3: exposing and developing the photoresist layer and the photoresist topcoat to form a resist pattern
30: photoresist topcoat
100: substrate
101: photoresist layer
102b: photoresist pattern

What is claimed is:

1. A resist topcoat composition comprising
a copolymer comprising a first structural unit represented by Chemical Formula M-1, a second structural unit represented by Chemical Formula M-2, and a third structural unit represented by at least one of Chemical Formula M-3A, Chemical Formula M-3B, or Chemical Formula M-3C; and
a solvent,
wherein the copolymer has an OHV (OH value) of about 5 mgKOH/g to about 100 mgKOH/g: 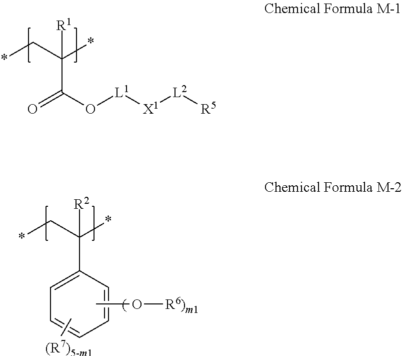
wherein, in Chemical Formula M-1 and Chemical Formula M-2,
R¹ and R² are each independently hydrogen or a substituted or unsubstituted C1 to C10 alkyl group,
L¹ and L² are each independently a single bond, a substituted or unsubstituted C1 to C10 alkylene group, or a combination thereof,
X¹ is a single bond, —O—, —S—, —S(═O)—, —S(═O)₂—, —C(═O)—, —C(═O)O—, —OC(═O)—, —OC(═O)O—, —NR^{a}— (wherein, R^{a} is hydrogen, deuterium, a substituted or unsubstituted C1 to C10 alkyl group), or a combination thereof,
R⁵ is hydrogen, fluorine, a hydroxy group, a substituted or unsubstituted C1 to C20 alkyl group, or a combination thereof,
R⁶ is hydrogen, or C(═O)R^{b},
R^{b} is a substituted or unsubstituted C1 to C10 alkyl group,
at least one of R⁵, L¹, or L² comprises a fluorine and a hydroxy group,
R⁷ is hydrogen, a halogen, a hydroxy group, a substituted or unsubstituted C1 to C10 alkyl group, or a combination thereof,
m1 is one of the integers of 1 to 4, and
* is a linking point; 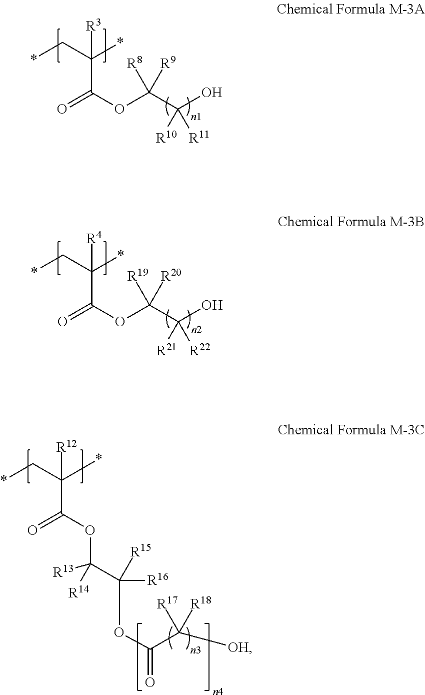
wherein, in Chemical Formula M-3A to Chemical Formula M-3C,
R³, R⁴, and R⁸ to R²² are each independently hydrogen or a substituted or unsubstituted C1 to C10 alkyl group,
n1 and n3 are each independently one selected from among integers of 1 to 10,
n2 is one of the integers of 2 to 5,
n4 is one of the integers of 1 to 5, and
* is a linking point.

2. The resist topcoat composition as claimed in claim 1, wherein
the first structural unit is represented by Chemical Formula 1: 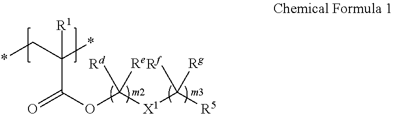
wherein, in Chemical Formula 1,
R¹ is hydrogen or a substituted or unsubstituted C1 to C10 alkyl group,
R^{d}, R^{e}, R^{f}, R^{g}, and R⁵ are each independently hydrogen, fluorine, a hydroxy group, a substituted or unsubstituted C1 to C20 alkyl group, or a combination thereof,
m2 and m3 are each independently one selected from among integers of 1 to 10,
X¹ is a single bond, —O—, —S—, —S(═O)—, —S(═O)₂—, —C(═O)—, —C(═O)O—, —OC(═O)—, —OC(═O)O—, —NR^{a}— (wherein, R^{a} is hydrogen, deuterium, or a substituted or unsubstituted C1 to C10 alkyl group), or a combination thereof, and
at least one selected from among R^{d}, R^{e}, R^{f}, R^{g}, and R⁵ comprises fluorine and a hydroxy group.

3. The resist topcoat composition as claimed in claim 1, wherein
the first structural unit is any one selected from among Group I: 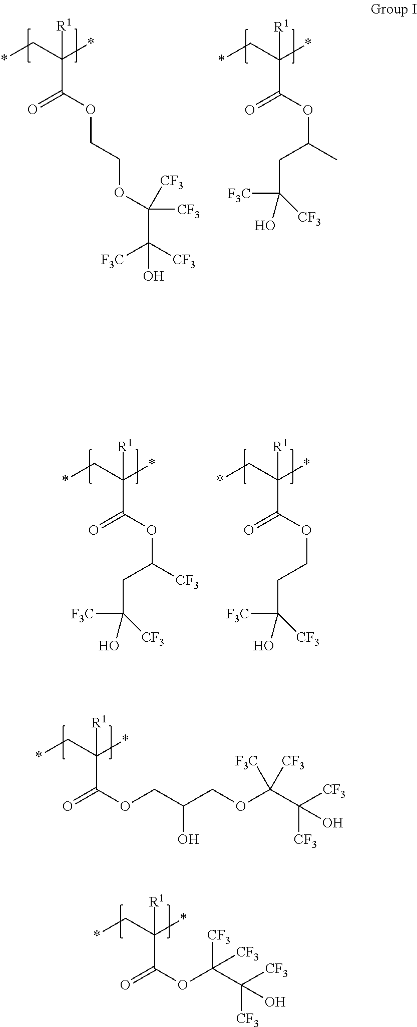
wherein, in Group I,
R¹ are each independently hydrogen or a methyl group, and * is a linking point.

4. The resist topcoat composition as claimed in claim 1, wherein
the second structural unit is represented by any one selected from among Chemical Formula 2-1 to Chemical Formula 2-4: 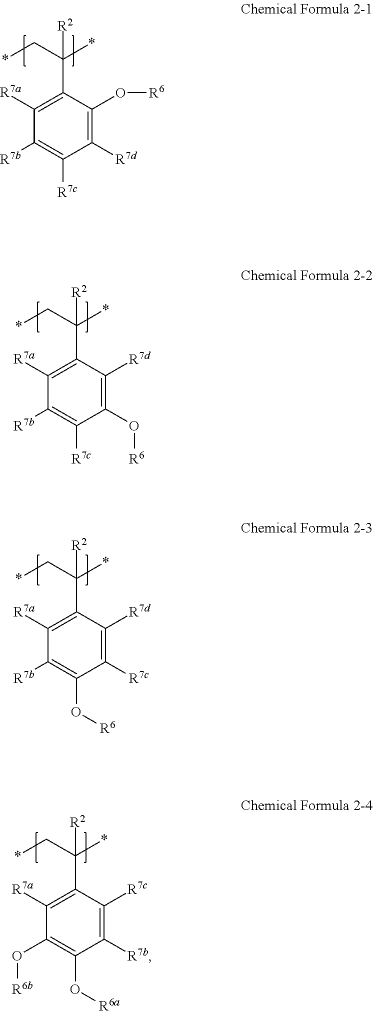
wherein, in Chemical Formula 2-1 to Chemical Formula 2-4,
R² is hydrogen or a methyl group,
R⁶, R^{6a}, and R^{6b} are each independently hydrogen or C(═O)R^{b},
R^{b} is a substituted or unsubstituted C1 to C5 alkyl group,
R^{7a}, R^{7b}, R^{7c}, and R^{7d} are each independently hydrogen, halogen, a hydroxy group, a substituted or unsubstituted C1 to C10 alkyl group, or a combination thereof, and
* is a linking point.

5. The resist topcoat composition as claimed in claim 1, wherein
at least one of R⁷ is a halogen.

6. The resist topcoat composition as claimed in claim 1, wherein
at least one of R⁷ is an iodine group.

7. The resist topcoat composition as claimed in claim 1, wherein
the second structural unit is any one selected from among Group II: 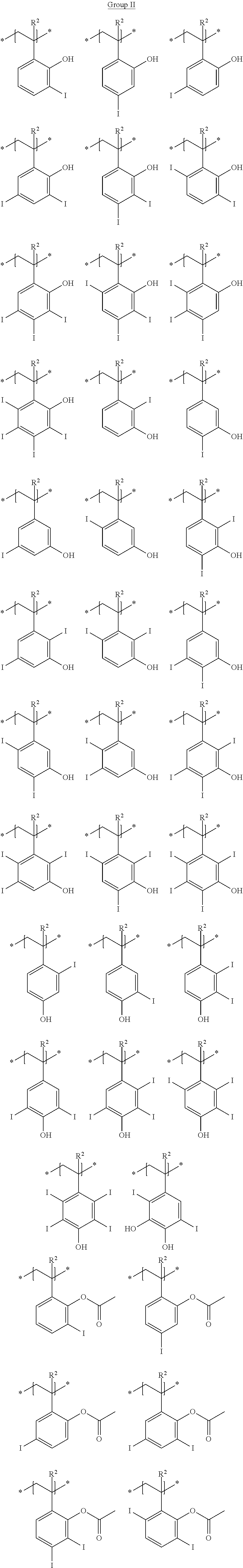 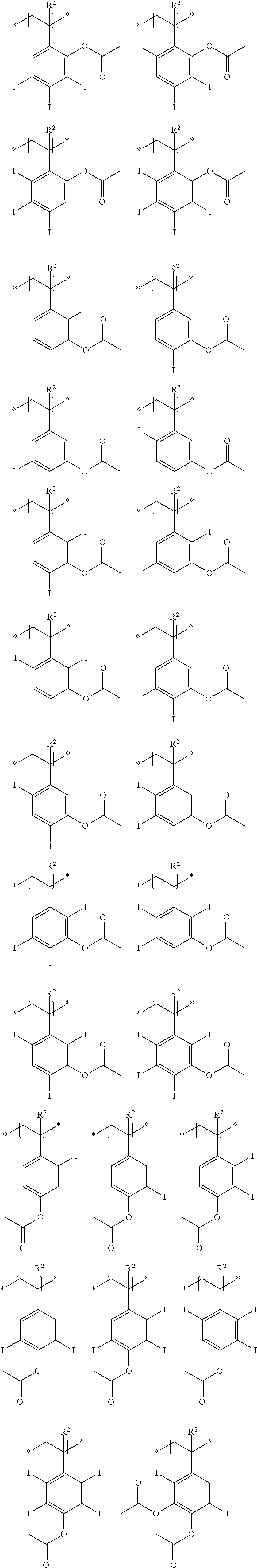
wherein, in Group II,
R² is each independently hydrogen or a methyl group, and * is a linking point.

8. The resist topcoat composition as claimed in claim 1, wherein
n1 in Chemical Formula M-3A is one selected from among integers of 1 to 5.

9. The resist topcoat composition as claimed in claim 1, wherein
n2 in Chemical Formula M-3B is one selected from among integers of 2 to 4.

10. The resist topcoat composition as claimed in claim 1, wherein
n3 in Chemical Formula M-3C is one selected from among integers of 1 to 5.

11. The resist topcoat composition as claimed in claim 1, wherein
the third structural unit is any one selected from among Group III: 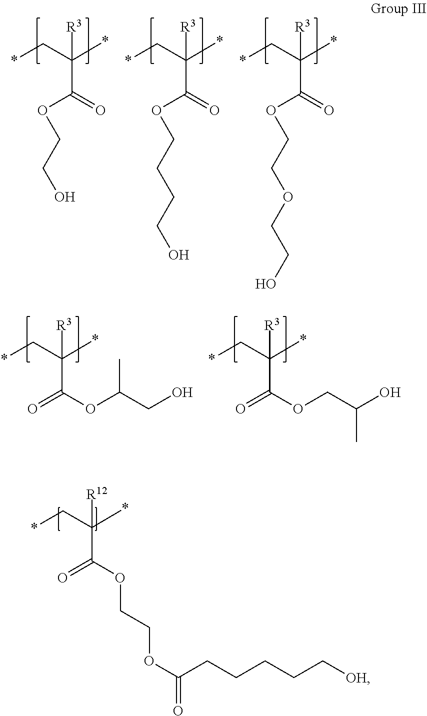
wherein, in Group III,
R³, R⁴, and R¹² are each independently hydrogen or a methyl group, and * is a linking point.

12. The resist topcoat composition as claimed in claim 1, wherein
the copolymer comprises about 30 mol % to about 95 mol % of the first structural unit, about 1 mol % to about 20 mol % of the second structural unit, and about 5 mol % to about 50 mol % of the third structural unit.

13. The resist topcoat composition as claimed in claim 1, wherein
a weight average molecular weight of the copolymer is about 1,000 g/mol to about 15,000 g/mol.

14. The resist topcoat composition as claimed in claim 1, wherein
the copolymer is any one selected from among Group IV: 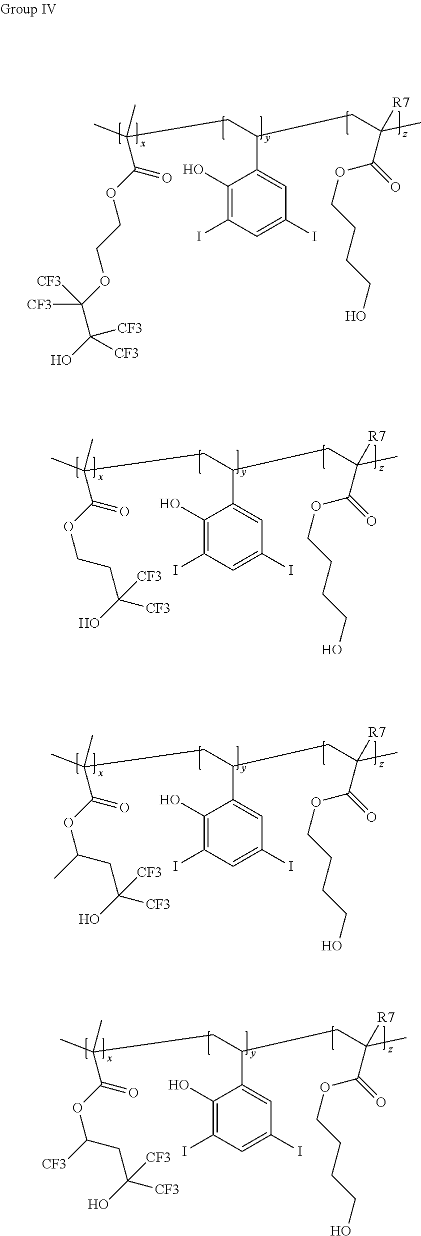 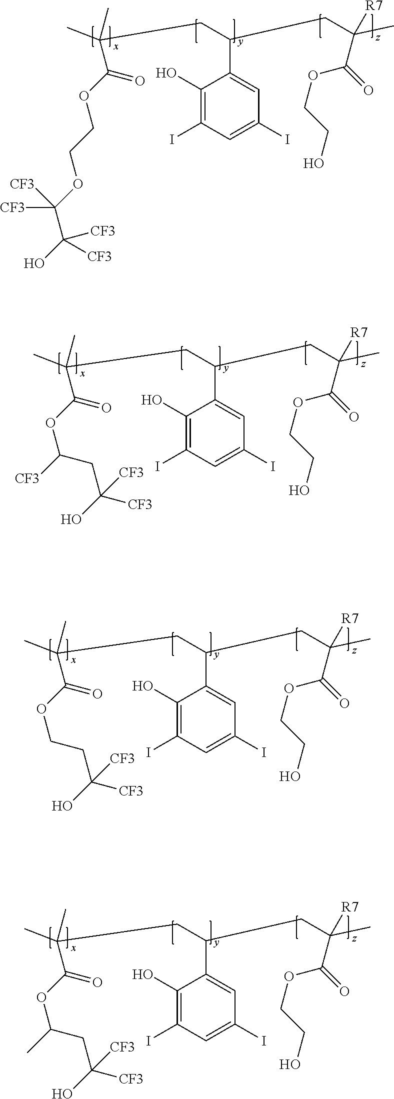 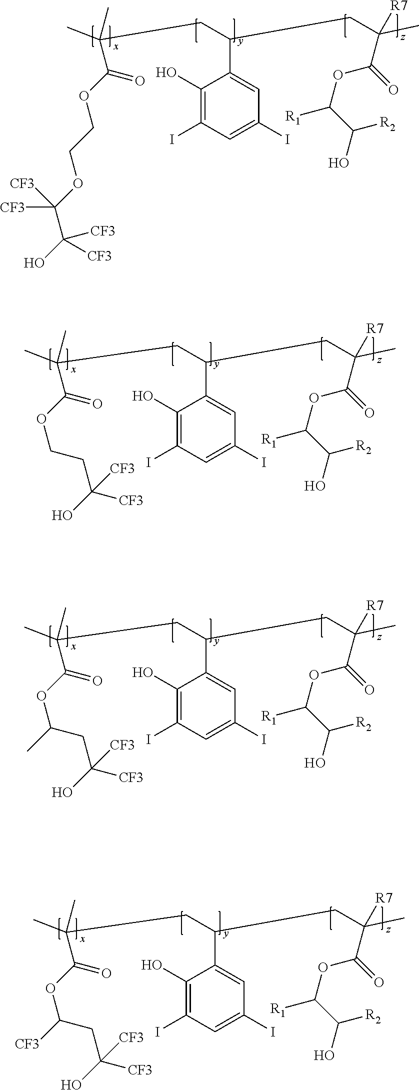 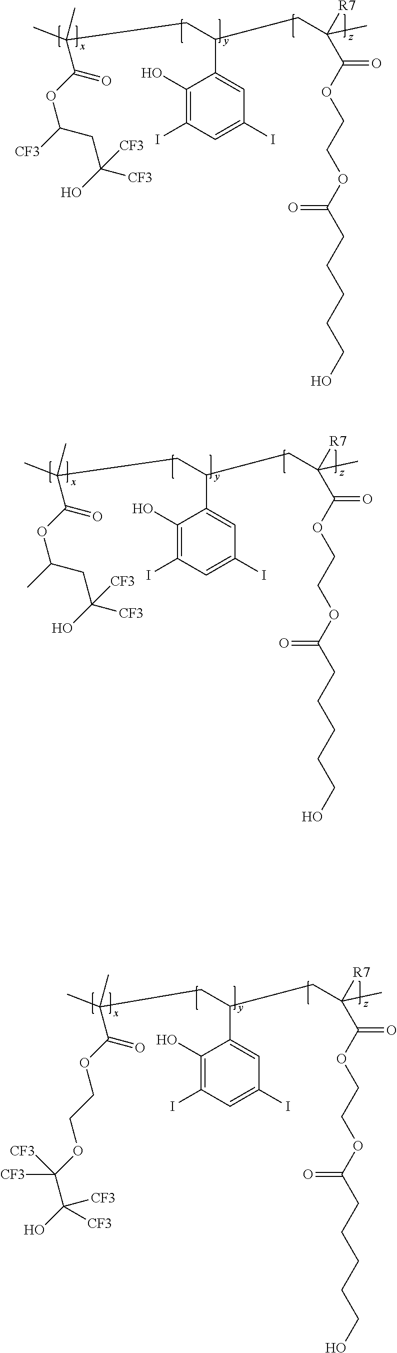 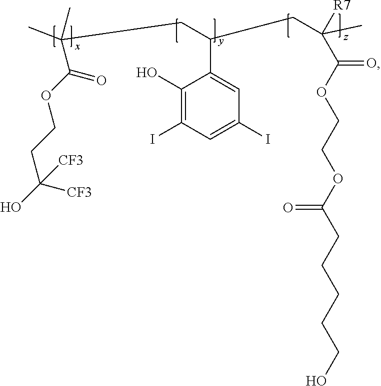
wherein, in Group IV,
R¹, R², and R⁷ are each independently hydrogen or a methyl group,
x is about 30 mol % to about 95 mol %, y is about 2 mol % to about 20 mol %, and z is about 5 mol % to about 50 mol %.

15. The resist topcoat composition as claimed in claim 1, wherein
the copolymer is included in an amount of about 0.1 wt % to about 10 wt % based on a total weight of 100 wt % of the resist topcoat composition.

16. The resist topcoat composition as claimed in claim 1, wherein
the solvent is an ether-based solvent represented by Chemical Formula 4: 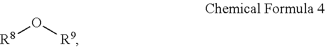
wherein, in Chemical Formula 4,
R⁸ and R⁹ are each independently a substituted or unsubstituted C1 to C20 alkyl group or a substituted or unsubstituted C3 to C20 cycloalkyl group.

17. A method of forming patterns, the method comprising
coating and heating a photoresist composition on a substrate to form a photoresist layer,
coating and heating the resist topcoat composition as claimed in claim 1 on the photoresist layer to form a topcoat, and
exposing and developing the topcoat and the photoresist layer to form a resist pattern.
